(19) United States
(12) Patent Application Publication
(10) Pub. No.: US 2025/0309125 A1
(43) Pub. Date: Oct. 2, 2025

(54) STACKED INTERCONNECT STRUCTURES AND METHODS OF FORMING THE SAME

(71) Applicant: Adeia Semiconductor Bonding Technologies Inc., San Jose, CA (US)

(72) Inventors: Belgacem Haba, Saratoga, MA (US); Rajesh Katkar, Milpitas, CA (US)

(21) Appl. No.: 18/987,970

(22) Filed: Dec. 19, 2024

Related U.S. Application Data
(60) Provisional application No. 63/571,717, filed on Mar. 29, 2024.

(51) Int. Cl. H01L 23/538; H01L 21/48; H01L 23/00; H01L 23/14

(52) U.S. Cl. CPC H01L 23/5385; H01L 21/4857; H01L 23/5386; H01L 24/08; H01L 24/80; H01L 23/147; H01L 2224/08225; H01L 2224/80895; H01L 2224/80896

(57) ABSTRACT

An interconnect structure includes a first substrate with first interconnect(s) embedded in a first dielectric layer, a second substrate including second interconnect(s) embedded in a second dielectric layer, and pair(s) of vias through the second dielectric layer. The second substrate is attached to the first substrate. Each interconnect includes a metal layer extending along a first direction, a pair of metal connectors extending from the metal layer in a second direction to a surface of the respective substrate, and at least one pair of vias through the second dielectric layer connected to at least one pair of connectors of the first substrate. The interconnect structure comprises at least one interconnect comprising a pair of vias of the second substrate connected to a first interconnect of the first substrate and at least another interconnect comprising a second interconnect of the second substrate.

### CROSS-REFERENCE TO RELATED APPLICATION

This application claims the benefit of U.S. Provisional Patent Application No. 63/571,717, filed Mar. 29, 2024, which is hereby incorporated by reference herein in its entirety.

### FIELD

The present disclosure relates to interconnect structures and methods of forming the same.

### BACKGROUND

An interconnect structure (e.g., a silicon bridge, an interposer, etc.) can provide high density interconnects between chips (e.g., central processing unit (CPU), graphics processing unit (GPU), neural processing unit (NPU), tensor processing unit (TPU), network switching devices, high bandwidth memory (HBM), etc.). As line width and pad pitch decreases and the number of input/outputs (I/Os) increase, the number of metal layers required for interconnecting chips and their widths and thicknesses may increase. The cost and complexity of integrating many metal layers in an interconnect structure may increase exponentially with number of layers. Accordingly, there exists a need for improved interconnect structures and methods of manufacturing the same.

### SUMMARY

Embodiments herein may provide for structures and methods to form stacked interconnects. Structures may include stacked interconnects (e.g., metal layers, metal connectors, metal vias, etc.) in dielectric layers as interconnect bridges, interposers, or interconnect bridges on interposers. The interconnects may have a fine line/space (L/S) or minimum width of line and spacing between lines. A fine L/S may be under 5 microns/5 microns, 2 microns/2 microns, 1 micron/1 micron, or about 1-2 microns (e.g., 1 micron/1 micron to about 2 microns/2 microns), etc. The interconnects may have a coarse L/S. A coarse L/S may be over 5 microns/5 microns, 10 microns/10 microns, or about 5-10 microns (e.g., 5 microns/5 microns to about 10 microns/10 microns), etc. The interconnects may have a combination of fine L/S and coarse L/S. The interconnects may be formed in organic dielectric layers (e.g., polyimide (PI), polybenzoxazole (PBO), benzocyclobutene (BCB), epoxy mold compound (EMC) resin, epoxy, resin, or molding material, etc.) or inorganic dielectric layers (e.g., silicon dioxide, silicon nitride, silicon oxynitride, silicon carbide, silicon oxycarbonitride, etc.), or a combination of organic and inorganic dielectric layers. Methods may include attaching two substrates comprising dielectric layers with embedded interconnects together, and removing one or more portions of the substrates (e.g., some silicon portions).

Advantageously, the structures and methods for forming stacked interconnects may provide for simpler fabrication processes by distributing metal layers between multiple substrates and attaching the substrates to form the interconnect structure instead of forming metal layers on one substrate. These may be especially useful when connecting chips (e.g., GPU, CPU, NPU, TPU, network switches, HBM, etc.) together, where a large number of interconnects may be needed.

A first general aspect includes an interconnect structure with a first substrate including one or more first interconnects embedded in a first dielectric layer attached to a second substrate including with one or more second interconnects embedded in a second dielectric layer, and one or more pairs of vias through the second dielectric layer. Each interconnect includes a metal layer extending along a first direction, a pair of metal connectors extending from the metal layer in a second direction to a surface of the respective substrate, and at least one pair of vias through the second dielectric layer connected to at least one pair of connectors of the first substrate. The interconnect structure comprises at least one interconnect comprising a pair of vias of the second substrate connected a first interconnect of the first substrate and at least another interconnect comprising a second interconnect of the second substrate.

In some embodiments, the interconnect structure may further include conductive features disposed in a silicon layer on the second substrate, where each conductive feature is connected to a respective interconnect.

In some embodiments, the first substrate is disposed on a silicon layer, and one or more through silicon vias through the silicon layer is connected to a corresponding first interconnect through a connector disposed in the first dielectric layer.

In some embodiments, the interconnect structure further includes through silicon vias disposed in a silicon layer between the first substrate and the second substrate, where the through silicon vias connect the at least one pair of first vias through the second dielectric layer to the at least one pair of connectors of the first substrate.

In some embodiments, the one or more pairs of vias are first vias, and the interconnect structure further includes a third substrate attached to the second substrate. The third substrate includes one or more third interconnects embedded in a third dielectric layer, one or more pair of second vias where at least one pair of second vias is electrically connected to the at least one pair of first vias, and one or more pairs of third vias disposed in the third substrate where at least one pair of third vias is connected to at least one pair of connectors of the one or more second interconnects.

In some embodiments, the one or more second interconnects have a line/space (L/S) of about 5 microns/5 microns to about 10 microns/10 microns and the one or more third interconnects have a L/S of about 1 micron/1 micron to about 2 microns/2 microns.

In some embodiments, the one or more pairs of vias are first vias, and the interconnect structure further includes a third substrate attached to the second substrate and a fourth substrate attached to the second substrate. The third substrate includes one or more third interconnects embedded in a third dielectric layer, and each of the third substrate and the fourth substrate include one or more second vias disposed in a respective substrate, where at least one second via is electrically connected to the at least one first via, and one or more third vias disposed in a respective substrate, where at least one third via is connected to at least one connector of the one or more second interconnects.

In some embodiments, the first dielectric layer includes organic material, and the second dielectric layer includes inorganic material.

A second general aspect includes a method including providing a first substrate including one or more first interconnects embedded in a first dielectric layer, a second substrate including one or more second interconnects embedded in a second dielectric layer, and one or more pairs of vias, where each interconnect includes a metal layer extending along a first direction and a pair of metal connectors extending from the metal layer in a second direction to a surface of the respective substrate. The first substrate is bonded to the second substrate to connect at least one pair of vias of the second substrate to at least one pair of connectors of the first substrate. The interconnect structure comprises at least one interconnect comprising a pair of vias of the second substrate connected a first interconnect of the first substrate and at least another interconnect comprising a second interconnect of the second substrate.

In some embodiments, the first substrate further includes a first silicon layer, the second substrate further includes a second silicon layer, and the method further includes removing the second silicon layer.

In some embodiments, the first substrate further includes a first silicon layer, the second substrate further includes a second silicon layer, and one or more pairs of partial through silicon vias are embedded in the second silicon layer. Each partial through silicon via includes a first end connecting to a corresponding interconnect or via through the second dielectric layer and a second end embedded in the second silicon layer. The method further includes partially removing the second silicon layer to form a bond pad.

In some embodiments, the first substrate is disposed on a silicon layer, and the method further includes forming one or more through silicon vias through the silicon layer to connect to a corresponding first interconnect through a connector disposed in the first dielectric layer.

In some embodiments, the one or more pairs of vias are first vias, and the method further includes providing a third substrate with one or more third interconnects embedded in a third dielectric layer, one or more pair of second vias through the third dielectric layer, and one or more pairs of third vias through the third dielectric layer. The third substrate is bonded to the second substrate to electrically connect at least one pair of second vias to the at least one pair of first vias, and to connect at least one pair of third vias to at least one pair of connectors of the one or more second interconnects.

A third general aspect includes a method including providing at least one interconnect structure. Each interconnect structure comprises bonded first and second substrates. Each first substrate comprises one or more first interconnects embedded in a first dielectric layer. Each second substrate comprises one or more second interconnects embedded in a second dielectric layer and one or more pairs of vias. Each interconnect structure comprises at least one interconnect comprising a pair of vias of the second substrate connected a first interconnect of the first substrate and at least another interconnect comprising a second interconnect of the second substrate. The method further includes providing an interposer including a silicon layer and one or more through silicon vias, and bonding the at least one interconnect structure to the interposer.

In some embodiments, bonding the at least one interconnect structure to the interposer includes directly bonding the at least one interconnect structure to the interposer.

In some embodiments, bonding the at least one interconnect structure to the interposer includes directly hybrid bonding the at least one interconnect structure to the interposer.

In some embodiments, a carrier substrate is attached to the at least one interconnect structure prior to bonding the at least one interconnect structure to the interposer, and the method further includes removing the carrier substrate from the at least one interconnect structure.

In some embodiments, the method further includes forming an organic material layer to dispose the at least one interconnect structure in the organic material layer, and forming one or more conductive vias in the organic material layer to connect to the one or more through silicon vias of the interposer.

In some embodiments, the method further includes forming one or more conductive posts adjacent to the at least one interconnect structure to connect to the one or more through silicon vias of the interposer, and forming an organic material layer to dispose the at least one interconnect structure and the one or more conductive posts in the organic material layer.

In some embodiments, the method further includes hybrid bonding a first semiconductor device and a second semiconductor device to the second substrate of the at least one interconnect structure. The first semiconductor device is electrically connected to the second semiconductor device through the at least one interconnect and the at least another interconnect of the interconnect structure.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A schematically illustrates a cross-sectional side view of a stacked interconnect structure, in accordance with some embodiments of the present disclosure;

FIGS. 1B-1C schematically illustrate using stacked interconnect structures to connect chips, in accordance with some embodiments of the present disclosure;

FIGS. 2A-2B schematically illustrate cross-sectional side views at different stages of a process flow to illustrate aspects of a method for forming example stacked interconnect structures, in accordance with some embodiments of the present disclosure;

FIGS. 3A-3D schematically illustrate cross-sectional side views of examples of stacked interconnect structures, in accordance with some embodiments of the present disclosure;

FIG. 4A schematically illustrates cross-sectional side views of examples of stacked interconnect structures, in accordance with some embodiments of the present disclosure;

FIG. 4B schematically illustrates using a stacked interconnect structure to connect chips, in accordance with some embodiments of the present disclosure;

FIG. 5A schematically illustrates cross-sectional side views of examples of stacked interconnect structures, in accordance with some embodiments of the present disclosure;

FIG. 5B schematically illustrates using a stacked interconnect structure to connect chips, in accordance with some embodiments of the present disclosure;

FIG. 6 schematically illustrates cross-sectional side views of examples interconnect structure to connect chips, in accordance with some embodiments of the present disclosure;

FIG. 7 schematically illustrates cross-sectional side views at different stages of a process flow to illustrate aspects of a method, in accordance with some embodiments of the present disclosure; and

FIGS. 8A-8B schematically illustrate hybrid bonding, in accordance with some embodiments of the present disclosure.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Separately fabricated chips may be connected together using an interconnect structure. For example, CPUs, GPUs, and HBMs may be separately fabricated and an interconnect structure may facilitate high-bandwidth connections between separate CPU, GPU, and HBM dies. As another example, some functionality (e.g., HBM interfaces, SerDes, I/O, fuses, any suitable functionality, etc.) can be extracted out from one or more chips (e.g., CPU, GPU, HBM chips, when chips get large, etc.) to another one or more chips and be manufactured at one process node (e.g., 28 nm), while the CPU, GPU, and/or logic can be manufactured (e.g., fabricated) at another process node (e.g., 3 nm). The separately fabricated chips manufactured at different nodes can be connected together using an interconnect structure. Examples of interconnect structures may be an interposer and silicon bridge, etc.

An interposer (e.g., silicon interposer) is a component used in electronics and semiconductor manufacturing to facilitate connections between different components or technologies. In some cases, the different components or technologies may not naturally interface with each other due to differences in form factor, electrical specifications, or other factors. An interposer may be a thin substrate that electrically connects two or more chips or dies, allowing them to communicate and work together. An interposer can provide routing for signals, power distribution, and through via (e.g. TSVs) as well as thermal management. Interposers can be useful to integrate different technologies or combine multiple chips into a single package. Interposers can be used in advanced packaging techniques (e.g., 2.5D and 3D packaging) which involve stacking multiple dies vertically or horizontally to achieve better performance, power efficiency, and miniaturization. Interposer may help overcome challenges related to different chip sizes, manufacturing processes, and electrical interfaces. However, using a large interposer (e.g., about 50 mm×50 mm or about 70 mm×70 mm to about 100 mm×100 mm and larger) may be expensive and difficult to fabricate. Further, fabricating metal interconnects between chips is complex and expensive because the number of inputs/outputs (I/Os) keeps increasing with time, leading to an increased number of metal layers in the interconnects and increased thickness (or widths) of the metal layers. The cost and complexity of integrating many metal layers in an interconnect structure may increase exponentially with number of layers.

Silicon bridge is an alternative to using a large interposer, and uses smaller bridges with multiple routing layers that may be embedded within an organic substrate (e.g., printed circuit board (PCB)) or an organic encapsulation (e.g., fanout wafer level packaging i.e. FO-WLP). For example, instead of using a large interposer or a silicon substrate covering an area of the chips and an area between chips, bridge technology uses smaller bridges or silicon bridge die covering an area between chips and edge portions of the chips. The smaller bridges may be embedded in a package substrate to enable connections between chips without the full size of the large interposer or embedded in an organic encapsulation. The size of the bridges may be about 10 mm×1 mm (e.g., about 50-500 times smaller than the footprint of an otherwise monolithic interposer). Silicon bridge technology may be used without through silicon vias (TSVs) that may be used with silicon interposers. Connections to a chip may be made through a package substrate (e.g., organic material, PCB) instead of silicon. However, fabricating metal interconnects between chips may remain complex and expensive because of increasing I/Os and increased number of metal layers in the interconnects.

Advantageously, the interconnect structures and manufacturing methods described herein may provide for a simpler and lower cost interconnect fabrication process. Rather than fabricating all the metal layers for interconnects in a single substrate, fabrication of the interconnects are divided between two or more substrates and subsequently bonded to reduce process complexity and cost.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

As described below, semiconductor substrates herein generally have a “device side,” e.g., the side on which semiconductor device elements are fabricated, such as transistors, resistors, capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

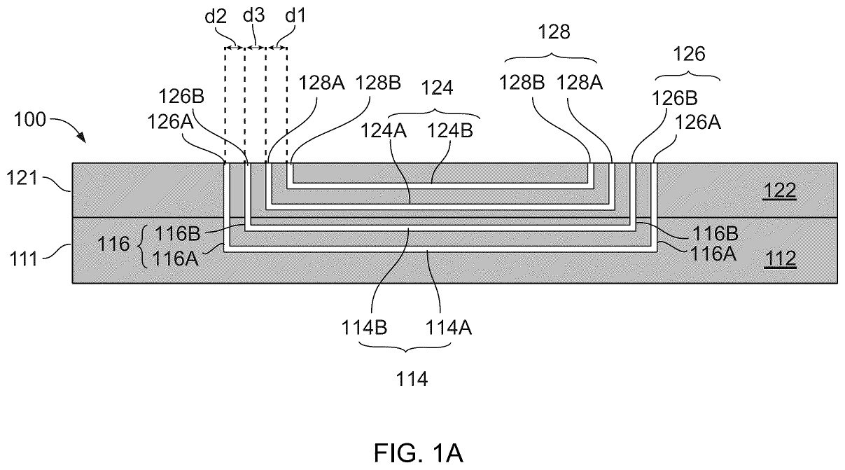

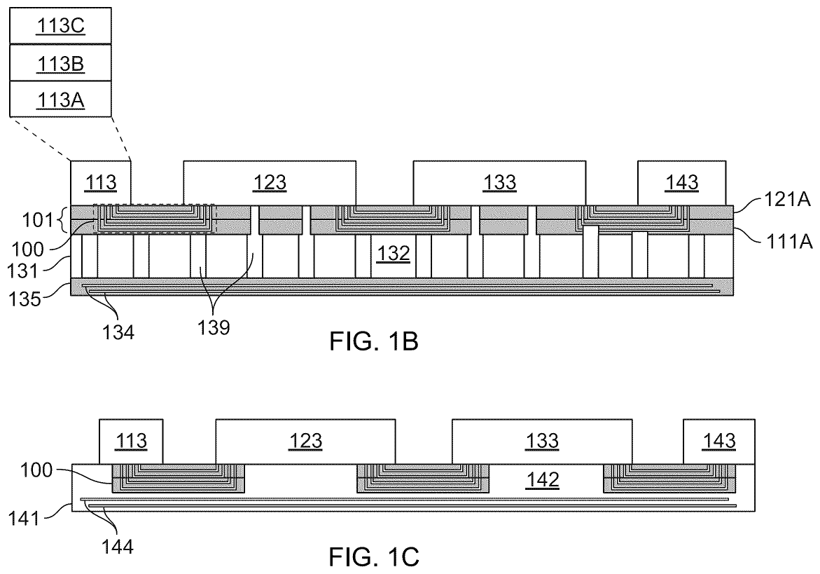

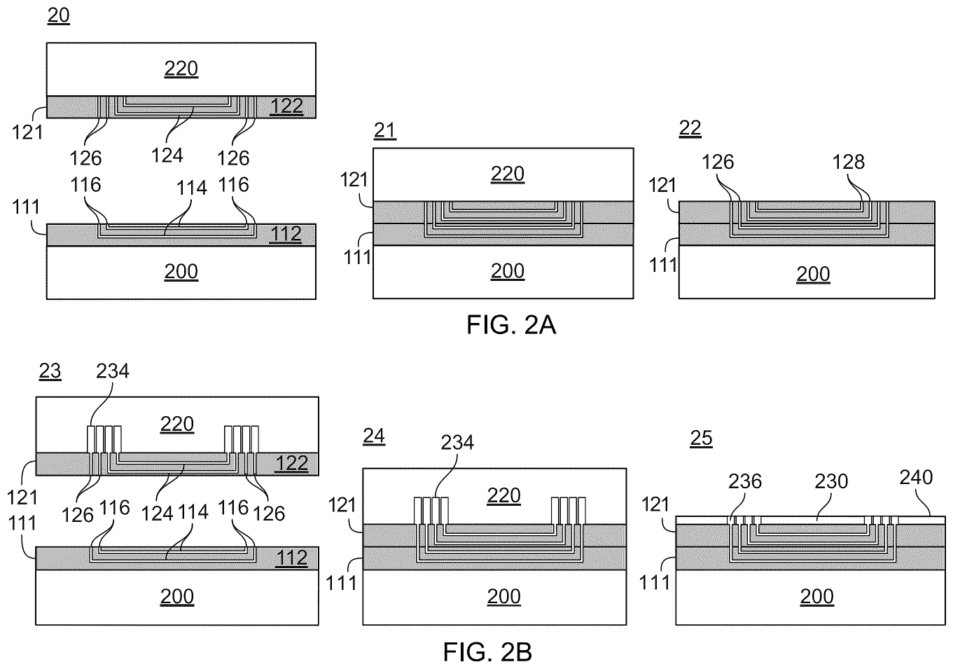

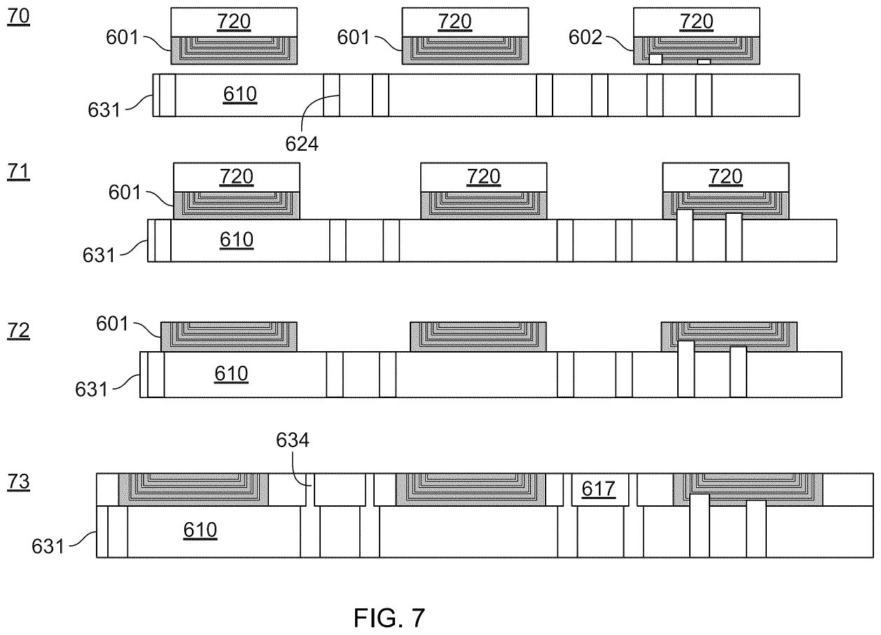

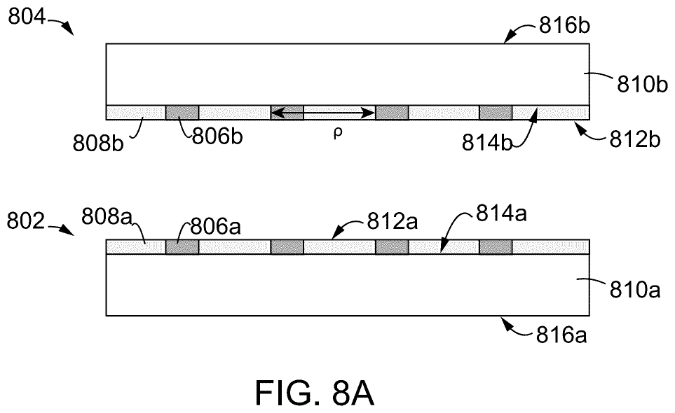

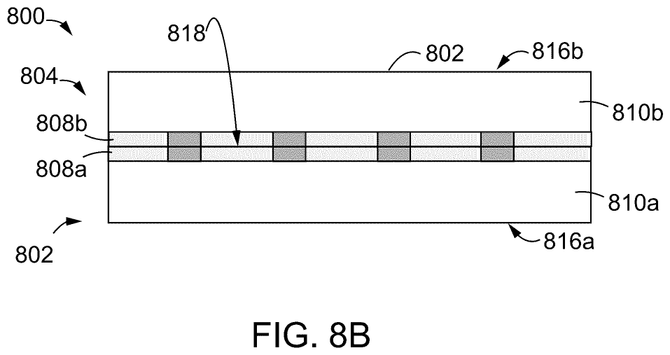

FIGS. 1A-1C, 2A-2B, 3A-3D, 4A-B, and 5A-B schematically illustrate various embodiments of a stacked interconnect structure. Although various embodiments may show a specific number of metal layers (e.g., two, four) in each substrate, any suitable number of layers may be formed on each substrate (e.g., one, two, three, four, six, eight or more, etc.). Although various embodiments may show a specific number of substrates or layers (e.g., two, three) that are attached to each other to form a stacked interconnect structure, any suitable number of substrates or layers may be combined to form a stacked interconnect structure (e.g., two, three, four or more, etc). In various embodiments, chips, substrates, and layers may be attached using any suitable technique (e.g., direct bonding, hybrid bonding, metal to metal bonding, soldering, etc.). FIG. 2A schematically illustrate aspects of a method that may be applied for forming stacked interconnects. FIG. 2B schematically illustrates aspects of a method that may be applied for forming stacked interconnects with a DBI layer. FIG. 6 schematically illustrate using an interconnect structure in connecting chips. Although FIG. 6-7 shows a specific number of substrate or layers (e.g., one, two) for an interconnect structure, the interconnect structure may have any suitable number of layers (e.g., one, two, three or more, etc.). In various embodiments, the interconnects in the interconnect structure may have a fine line/space (L/S) or minimum width of line and spacing between lines. A fine L/S may be under 5 microns/5 microns, 2 microns/2 microns, 1 micron/1 micron, or about 1-2 microns (e.g., 1 micron/1 micron to about 2 microns/2 microns), etc. In various embodiments, the interconnects may have a coarse L/S. A coarse L/S may be over 5 microns/5 microns, 10 microns/10 microns, or about 5-10 microns (e.g., 5 microns/5 microns to about 10 microns/10 microns), etc. In various embodiments, the interconnects may have a combination of fine L/S and coarse L/S. In various embodiments, the interconnects may be formed in any suitable organic dielectric layers such as those mentioned throughout the present disclosure (e.g., polyimide (PI), polybenzoxazole (PBO), benzocyclobutene (BCB), epoxy mold compound (EMC) resin, epoxy, resin, or molding material, etc.). In various embodiments, the interconnects may be formed in any suitable inorganic dielectric layers such as those mentioned throughout the present disclosure (e.g., silicon dioxide, silicon nitride, silicon oxynitride, silicon carbide, silicon oxycarbonitride, etc.). In various embodiments, the interconnects may be formed in a combination of organic and inorganic dielectric layers. FIGS. 8A-8B illustrate a hybrid bonding method for bonding substrates (e.g., substrates comprising interconnects to substrates comprising interconnects and vias, interposers to interconnect layers, chips to stacked interconnect structures, etc.).

FIG. 1A shows an illustrative schematic sectional side view of an example stacked interconnect structure 100. The stacked interconnect structure 100 comprises a first substrate 111 and a second substrate 121. Each substrate comprises interconnects (e.g., conductive layers, conductive connectors, etc.) embedded within a dielectric layer to connect a conductive region of the surface of the substrate to another conductive region of the surface of the substrate. The second substrate 121 (e.g., upper substrate) further comprises conductive vias 128 to enable interconnects of the first substrate 111 (e.g., underlying substrate) to be accessed from the second substrate 121. The stacked interconnect structure 100 can comprise interconnects from the first substrate 111 and the second substrate 121. The first substrate 111 and second substrate 121 may be attached to each other using any suitable technique (e.g., direct bonding, hybrid bonding, metal to metal bonding, soldering, etc.). In some embodiments, the first substrate 111 and the second substrate 121 are hybrid bonded to each other.

The first substrate 111 comprises a first dielectric layer 112 in which a first set of metal layers 114 (e.g., horizontal portions of a first set of interconnects, metal layer 114A and metal layer 114B), and a corresponding first set of metal connectors 116 (e.g., vertical portions of a first set of interconnects, first pair of connectors 116A and second pair of connectors 116B) may be embedded. The first substrate 111 comprises two interconnects (e.g., each interconnect comprising a horizontal portion or metal layer 114A-B and corresponding vertical portions or metal connectors 116A-B). The metal connectors 116A-B may be connected to each end of a metal layer 114A-B.

The second substrate 121 comprises a second dielectric layer 122 in which a second set of metal layers 124 (e.g., horizontal portions of a second set of interconnects, metal layer 124A and metal layer 124B) and a corresponding second set of metal connectors 128 (e.g., vertical portions of the second set of interconnects, metal connectors 128A and metal connectors 128B) may be embedded. The second substrate 121 further comprises a set of metal vias 126 (e.g., pair of vias 126A and pair of vias 126B) embedded in the second dielectric layer 122. The set of metal vias 126 can connect to the first set of interconnects of the first substrate 111. The second substrate 121 comprises two interconnects (e.g., each interconnect comprising a horizontal portion or metal layer 124A-B and corresponding vertical portions or metal connectors 128A-B). The metal connectors 128A-B may be connected to each end of a metal layer 124A-B. Each pair of metal vias 126A-B of the second substrate 121 is connected to a corresponding pair of vertical portions or metal connectors 116A-B of the first substrate 112. A pair of metal vias 126A-B may be connected to a pair of metal connectors 116A-B, each metal connector 116A-B of the pair being connected to a corresponding end of a horizontal portion or metal layer 114A-B of the first interconnects.

The dielectric layers 112 and 122 may each comprise a dielectric material. The dielectric material may comprise silicon dioxide, silicon nitride, silicon oxynitride, or any suitable dielectric material such as those mentioned throughout the present disclosure. Although figures suggest only one dielectric layer 112 and dielectric layer 122 within the first substrate 111 and second substrate 121, two or more dielectric materials or materials can also be used. In some embodiments, a thin base substrate (e.g. silicon, glass, etc.) can also be the part of the first substrate 111 and/or second substrate 121. In some embodiments, dielectric layers 112 and 122 may be formed from same or different dielectric materials (e.g., dielectric layer 112 comprises oxide and nitride and dielectric layer 122 comprises oxide, oxynitride and nitride).

The metal layers 114 and 124, metal connectors 116 and 128, and metal vias 126 may each comprise a metal material. The pitch or separation (e.g., distance d1) between connectors 128A and 128B may be the same as the pitch or separation (e.g., distance d2) between vias 126A and 126B. The separation (e.g., distance d3) between a connector 128A and adjacent via 126B may be same as the pitch or separation (e.g., distance d1 or d2) between connectors 128 and between vias 126. In some embodiments, the distance d1, d2, and d3 may be a same distance (e.g., d1, d2, and d3 are a same distance), a different distance (e.g., d1, d2, and d3 are different distances), or some combination thereof (e.g., d1 and d2 may be a same distance and d3 may be different, d1 and d3 may be a same distance and d2 may be a different distance, d2 and d3 may be a same distance and d1 may be a different distance). Examples of metal materials may be copper, copper alloys, nickel, nickel alloys, aluminum, aluminum alloys, etc. In some embodiments, conductive layers, conductive connectors, and/or conductive vias may be used in place of metal layers, metal connectors, and/or metal vias. Conductive layers, conductive connectors, and conductive vias may each comprise a conductive material. The conductive material may be a metal material, a transparent conductive material, or any suitable conductive material such as those mentioned throughout the present disclosure.

The set of metal vias 126 may be connected to the first set of metal connectors 116. Each set of metal layers (e.g., metal layers 114 and 124) may comprise of one or more horizontal parallel layers. Each set of metal connectors (e.g., metal connectors 116, 128) may comprise of one or more pairs of vertical parallel metal connectors. Each set of metal vias (e.g., metal via 126) may comprise of one or more pairs of vertical parallel metal vias. In some embodiments, the metal layers, metal connectors, and metal vias may be formed using a serial process of interconnect metallization. For example, the metallization process may include alternately forming (e.g., depositing) dielectric (e.g., silicon oxide, silicon nitride) layers and metal layers. The metal connectors and metal vias may be formed using a process that includes etching the dielectric layer and filling with metal.

FIG. 1B shows an illustrative schematic sectional side view of an example of the stacked interconnect structures 100 in a stacked interposer 101 connecting one or more chips. The stacked interposer 101 is attached to a bottom interposer 131 and an interconnect layer 135 comprising interconnects 134. The stacked interposer 101 may be about 45 mm in size or about 30 mm to 50 mm in size. A stacked interposer 101 may be about 30 mm×30 mm to about 50 mm×50 mm. A stacked interposer 101 may be about 100 mm×100 mm to about 120 mm×120 mm in size. In some embodiments, a stacked interposer 101 may be used at a wafer level or a panel level.

The stacked interposer 101 comprises a plurality of stacked interconnect structures 100 used to connect a plurality of semiconductor devices or chips (e.g., first chip 113, second chip 123, third chip 133, and fourth chip 143). The stacked interposer comprises a first substrate 111A and a second substrate 121A. The first substrate 111A may be similar to or the same as the first substrate 111 except that it may include multiple sets of interconnects. The second substrate 121A may be similar to or the same as the second substrate 121 except that it may include multiple sets of interconnects that may correspond to and are connected to the sets of interconnects in the first substrate 111A. The first substrate 111A and the second substrate 121A may also include vias that correspond to and are connected to each other to form a via through the stacked interposer 101.

The plurality of semiconductor devices or chips may be attached to the stacked interposer 101 by bonding (e.g., direct bonding, hybrid bonding), soldering, or any suitable technique. In some embodiments, the interconnect structures 100 may electrically connect chips 113, 123, 133, and 143 together. In some embodiments, all chips may not be connected to each other. A first chip 113 and a second chip 123 may be connected with a first interconnect structure 100 (e.g., left most interconnect structure 100 in FIG. 1B). A second chip 123 and a third chip 133 may be connected with a second interconnect structure (e.g., center interconnect structure 100 in FIG. 1B). A third chip 133 and a fourth chip 143 may be connected with a third interconnect structure (e.g., right most interconnect structure 100 in FIG. 1B). In some embodiments one or more of chips 113, 123, 133, and 143 may be a stack of chips. For example, as shown in FIG. 1B, chip 113 may be a stack of chips (e.g., chip 113A, chip 113B, and chip 113C). Although three chips are shown, any suitable number of chips may be stacked (e.g., 2, 3, 4 or more chips). Any suitable chip (e.g., chips 113, 123, 133, 143, and other chips as described in embodiments of the present disclosure) may be a stack of chips, and each chip or stack of chips may have a same or similar height or different heights. In some embodiments, a first semiconductor device (e.g., chip 113) and a second semiconductor device (e.g., chip 123) are hybrid bonded to the second substrate 121 of the interconnect structure (e.g., interconnect structure 100). The first semiconductor device (e.g., chip 113) may be electrically connected to the second semiconductor device (e.g., chip 123) through at least one interconnect (e.g., the first interconnects of the first substrate 111 and through the vias 126 of the second substrate 121) and at least another interconnect (e.g., second interconnect of the second substrate 121) of the interconnect structure.

In some embodiments, the chips may be any suitable type of chip (e.g., CPU, GPU, HBM, NPU, TPU, network switch, etc.). In some embodiments, chip 133 may be a CPU or a GPU chip, and chips 123 and 143 may be HBM chips. In some embodiments, there may be two GPUs together (e.g., chip 123 and chip 133 may be CPU or GPU chips), and chips 113 and chip 143 may be HBM chips. In some embodiments, there may be any suitable number of chips. There may be 1 GPU and 4 to 6 HBMs. In some embodiments, the spacing between adjacent GPU and HBM chips may be 100 microns, or about 50 to 300 microns, or about 2 mm to 4 mm.

The first substrate 111A may be attached to an interposer 131. A second substrate 121A comprising metal interconnects may be further bonded onto substrate 111A. Substrates 111A and 121A may comprise dielectric layers. In some embodiments, the first and second substrates 111A and 121A may be bonded together to form the stacked interposer 101, and the stacked interposer 101 may be attached to the interposer 131. Structures similar to interconnect structure 100 may contact one or more of the chips 113, 123, 133, and 143 (e.g., chip 113 to chip 123, chip 123 to chip 133, chip 133 to chip 143). The interposer 131 may comprise a silicon layer 132 and TSVs 139. The TSVs 139 may connect to vias in the stacked interposer 101. In some embodiments, TSVs 139 may connect to vias in the stacked interposer 101 using one or more redistribution layers (RDL) between interposer 101 and 131. In some other embodiments, metal vias 126 or metal connectors 128 may connect to one or more of the chips 113, 123, 133, and 143 using one or more RDLs.

In some embodiments, an interconnect layer 135 may be disposed below the interposer 131. The interconnect layer 135 may comprise interconnects 134 (e.g., routing lines). The interconnects 134 may be disposed in a semiconductor material (e.g., silicon) or a dielectric material (e.g., organic, inorganic, or any suitable dielectric material such as those mentioned in the present disclosure). In some embodiments the interconnect layer 135 may be a substrate attached to the interposer 131. In some embodiments, the interconnect layer 135 may be formed on the interposer 131.

FIG. 1C shows an illustrative schematic sectional side views of examples of the stacked interconnect structures 100 as stacked bridge structures disposed (e.g. embedded) in a packaging substrate (e.g., PCB, organic encapsulation material (e.g. epoxy mold compound, resin, polyimide, etc.), ceramic, glass, etc.) being used to connect one or more chips (e.g., CPU chip, GPU chip, HBM chip, etc.) together (e.g., to act as a monolithic chip). The pad pitch for bridge structures may be less than about 40 microns, 20 microns, 10 microns, 5 microns, 2 micron or under 1 micron. The size of the bridges may be in a range from about 2 mm to about 8 mm. A size of a bridge may be about 10 mm×1 mm in size, or about 6 mm×6 mm in size. A size of the bridge may be less than about 15 mm, 10 mm, 8 mm, 5 mm, 2 mm, or 1 mm. In some embodiments, size may refer to a length, a width, or both a length and a width. A stacked bridge (e.g., interconnect structure 100) may be about 100× smaller than an interposer 101. In some embodiments, an interposer 101 may be more than about 40× or more than about 50× the area of the bridge.

FIG. 1C shows stacked interconnect structures 100 as stacked bridges to connect semiconductor devices or chips 113, 123, 133, and 143 together. The interconnect structures 100 are used as bridges embedded in a packaging substrate 141 comprising packaging material 142 (e.g., PCB, organic material or dielectric, ceramic, glass, etc.). In some embodiments, the packaging substrate may comprise bottom interconnects 144. In some embodiments, the interconnect structures 100 may electrically connect chips 113, 123, 133, and 143 together. In some embodiments, all chips may not be connected to each other. A first chip 113 and a second chip 123 may be connected with a first interconnect structure 100 (e.g., left most interconnect structure 100 in FIG. 1C). A second chip 123 and a third chip 133 may be connected with a second interconnect structure (e.g., center interconnect structure 100 in FIG. 1C). A third chip 133 and a fourth chip 143 may be connected with a third interconnect structure (e.g., right most interconnect structure 100 in FIG. 1C). In some embodiments one or more of chips 113, 123, 133, and 143 may be a stack of chips (e.g., as shown in FIG. 1B, chip 113 may be a stack of chips (e.g., chip 113A, chip 113B, and chip 113C)). Although three chips are shown, any suitable number of chips may be stacked (e.g., 2, 3, 4 or more chips). Any suitable chip (e.g., chips 113, 123, 133, 143, and other chips as described in embodiments of the present disclosure) may be a stack of chips, and each chip or stack of chips may have a same or similar height or different heights. In some embodiments, a first semiconductor device (e.g., chip 113) and a second semiconductor device (e.g., chip 123) are hybrid bonded to the second substrate 121 of the interconnect structure (e.g., interconnect structure 100), and the first semiconductor device (e.g., chip 113) is electrically connected to the second semiconductor device (e.g., chip 123) through the first interconnects of the first substrate 111 through the vias 126 of the second substrate 121.

In some embodiments, the semiconductor devices or chips may be any suitable type of chip (e.g., CPU, GPU, HBM, etc.). In some embodiments, chip 133 may be a CPU or a GPU chip, and chips 123 and 143 may be HBM chips. In some embodiments, there may be two GPUs together (e.g., chip 123 and chip 133 may be CPU or GPU chips), and chips 113 and chip 143 may be HBM chips. In some embodiments, there may be any suitable number of chips. There may be 1 GPU and 4 to 6 HBMs. In some embodiments, the spacing between adjacent GPU and HBM chips may be about 100 microns, or about 50 to 300 microns, or about 2 mm to 4 mm.

FIGS. 2A-2B schematically illustrate methods for forming stacked interconnect structures (e.g., stacked interconnect structure 100 of FIG. 1A) at different stages of manufacturing, in accordance with embodiments of the present disclosure. The methods shown in FIGS. 2A-2B use a parallel process of forming the metal layers instead of a serial process of forming the metal layers. For example, instead than forming four metal layers on one substrate, two metal layers may be formed on one substrate and two metal layers may be formed on another substrate, and both substrates may be attached to each other (e.g., directly bonded, hybrid bonded) to form a substrate (e.g., directly bonded substrate) with four total metal layers.

In the method shown in FIG. 2A, the ends of stacked interconnects (e.g., vertical portions, connectors 128, vias 126) in at least one of the attached substrates 121 may be exposed, in accordance with embodiments of the present disclosure. Generally, the method may include removing at least a portion of the silicon layer 220 of at least one substrate 121 after two substrates 111, 121 with embedded interconnects are attached (e.g., bonded) together. In some embodiments, additional metal layers may be added by stacking another substrate.

At block 20, the method includes providing the first substrate 111 and the second substrate 121. The method includes providing the first substrate 111 on a silicon layer 200, and providing the second substrate 121 on a silicon layer 220. Rather than forming four metal layers on a single substrate, two metal layers may be formed on two separate substrates and then combined (e.g., directly bonded, hybrid bonded). For example, two metal layers 114 (e.g., horizontal portions of first interconnects) disposed in a dielectric material may be formed on a silicon layer 200, and two metal layers (e.g., horizontal portions 124 of second interconnects) disposed in a dielectric material may be formed on a silicon layer 220. The silicon layer (e.g., silicon layer 200 or 220) may be a silicon substrate or wafer. Providing the first substrate 111 and the second substrate 121 may comprise alternately forming or depositing dielectric (e.g., silicon oxide, silicon nitride) layers and metal layers, and forming metal connectors and metal vias by etching particular dielectric layers and filling with metal. A method may include depositing oxide on silicon layer 200 or 220, depositing a metal layer on oxide, depositing an oxide layer on metal, forming a via in the oxide, and repeating the process for the number of metal layers on the substrate. Although two metal layers (e.g., metal layer 114A and 114B) are shown to be formed on two separate substrates (e.g., substrates 112 and 122), one or both substrate (e.g., substrate 112, substrate 122) may have less or more than 2 metal layers (for example 1 and 3 metal layers, or 3 and 3 metal layers, 4 and 4 metal layers, or 2 and 4 metal layers, or 1 and 5 metal layers, or 3 and 2 metal layers, etc.).

At block 21, the method includes attaching first substrate 111 to the second substrate 121. The first substrate 111 and underlying silicon layer 200 may be attached to the second substrate 121 and underlying silicon layer 220. In some embodiments, the substrates are hybrid bonded, and a surface of the dielectric layer 112 is bonded to a surface of the dielectric layer 122 (e.g., forming direct dielectric bonds) and the set of metal vias 126 may be connected to the first set of metal connectors 116 (e.g., via direct metal bonds).

At block 22, the method includes removing the silicon layer 220 of the second substrate 121 and exposing the set of metal vias 126 and the second set of metal connectors 128. In some embodiments, the silicon layer 220 of the second substrate 121 may be removed by etching.

In the method shown in FIG. 2B, through silicon vias (TSVs) or bond pads connected to the stacked interconnects are exposed instead of the interconnects, in accordance with embodiments of the present disclosure. Generally, the method may include partially removing a silicon layer with embedded TSVs in one substrate after two substrates with embedded interconnects are attached (e.g., bonded) together.

At block 23, the method includes a providing a first substrate 111 on a silicon layer 200 and providing a second substrate 121 on a silicon layer 220. Block 23 of FIG. 2B is similar to block 20 of FIG. 2A, except that the silicon layer 220 includes embedded TSVs 234.

At block 24, the first and second substrates 111 and 121 may be attached together. Block 24 of FIG. 2B is similar to block 21 of FIG. 2A, except that the silicon layer 220 includes embedded TSVs 234.

At block 25, a portion of the silicon layer 220 with embedded TSVs 234 is removed (e.g., etched). For example, partial removal of the silicon layer 220 and embedded TSVs 234 may form a DBI layer 240 comprising bond pads 236 (e.g., conductive features, TSVs) disposed in a silicon layer 230 (e.g., thin silicon layer). In some embodiments, the silicon layer 230 may be a few microns thick (e.g., 0.1-10 microns, about 1 micron, about 10 microns, less than about 10 microns, greater than about 10 microns).

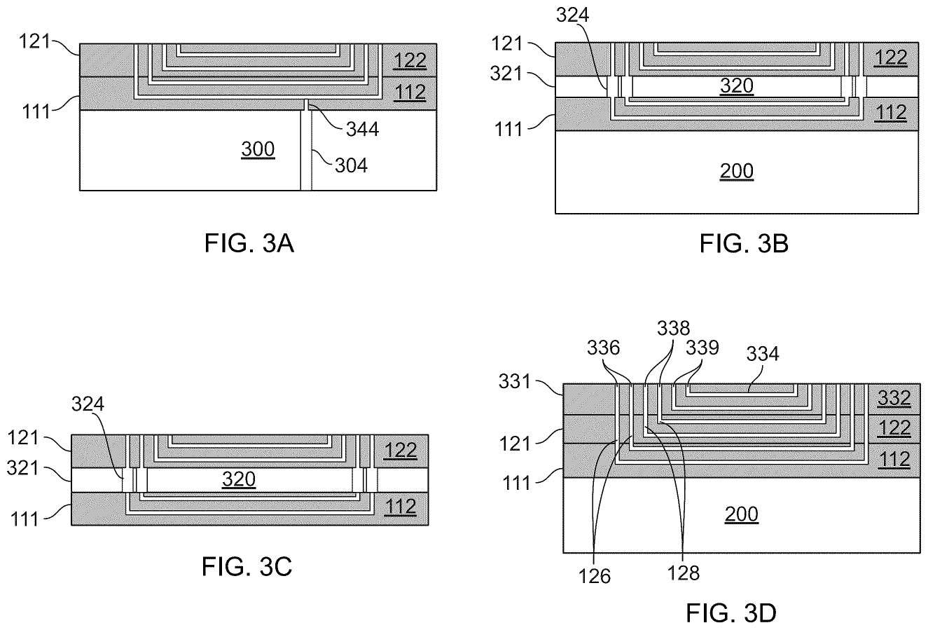

FIGS. 3A-3D schematically illustrate examples of stacked interconnect structures. FIG. 3A may show a variation of the stacked interconnect structure 100 with a backside connection through a silicon layer. FIG. 3B may show a variation of the stacked interconnect structure 100 with an intervening DBI layer between the first and second substrates and a backside silicon layer. FIG. 3C may show the variation of the stacked interconnect structure of FIG. 3B without the backside silicon layer. FIG. 3D may show a variation of the stacked interconnect structure 100 using three stacked substrates instead of two stacked substrates.

FIG. 3A shows a structure that is similar to structure shown at block 22 of FIG. 2A where a first substrate 111 is attached to a second substrate 121, except that the silicon layer 300 (similar to silicon layer 200 in block 22) of the first substrate 111 may further include one or more embedded vias (e.g., shown as one via 304). Although only one via 304 is shown, there may be any suitable number of vias in silicon layer 300. The first and second substrates 111 and 121 may comprise dielectric layers 112 and 122 respectively with embedded interconnects within the dielectric layers. The via 304 embedded in the silicon layer 300 may be connected to an interconnects in dielectric layer 112 via a metal connector 344 disposed in the dielectric layer 112. In some embodiments, an RDL may be used to connect via 304 embedded in the silicon layer to one or more interconnects in dielectric layer 112. In some embodiments, via 304 may be within the shadow, perimeter, or footprint of metallization in dielectric layers 112 and 122. In some other embodiments, via 304 may be outside the shadow, perimeter, or footprint of metallization in dielectric layers 112 and 122.

In FIG. 3B, a third substrate 321 is disposed between the first substrate 111 and the second substrate 121. The third substrate 321 may comprise one or more DBI layers. For example, the third substrate may comprise a silicon layer 320 and through silicon vias 324 (e.g., bond pads). In some embodiments, the third substrate 321 may comprise conductive features disposed in dielectric layers. The first substrate 111 may further comprise a silicon layer 200 below the dielectric layer 112. In some embodiments, a redistribution layer may be between silicon 320 and dielectric layer 112.

FIG. 3C shows a stacked interconnect structure similar to the one shown in FIG. 3B, except the silicon layer 200 below the dielectric layer 112, is removed. The silicon layer 200 may be removed by etching. In some embodiments, a redistribution layer may be between silicon 320 and dielectric layer 112.

FIG. 3D shows a structure similar to structure shown in block 22 of FIG. 2A where a first substrate 111 is attached to a second substrate 121, except a third substrate 331 is further attached to the second substrate 121. The first, second, and third substrates 111, 121, and 331 may comprise dielectric layers 112, 122, and 332, respectively, and embedded interconnects within the dielectric layers. The dielectric layer 332 may be similar to dielectric layers 112 and 122 and comprise any suitable dielectric layer or layers, such as those mentioned throughout the present disclosure. The first substrate 111 may comprise a silicon layer 200 below the dielectric layer 112. The third substrate 331 may comprise metal layers 334 and corresponding metal connectors 339. The third substrate may further comprise metal vias 338 corresponding to and connected to metal connectors 128 in the second substrate 121, and metal vias 336 corresponding to and connected to metal vias 126 in the second substrate 121. The metal layers 334, metal connectors 339, and vias 336 may be similar to metal layers 114, 124, metal connectors 116, 126, and vias 126, respectively, and comprise any suitable metal or conductive materials such as those mentioned in the present disclosure. Although only three substrates have been shown in FIG. 3D, any number of substrates may be stacked together to form any number of stacked interconnects. In some embodiments, a silicon layer 320 may be between any suitable substrates (e.g., substrates 112 and 122, substrates 122 and 332) of FIG. 3D. In some embodiments, an RDL may be between a silicon layer 320 and a substrate (e.g., substrate 112, substrate 122).

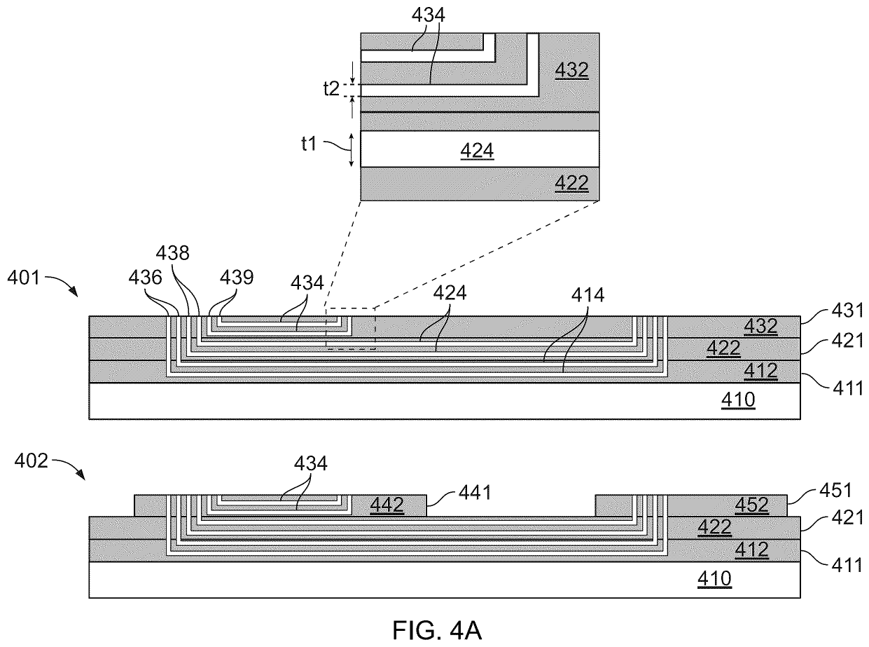

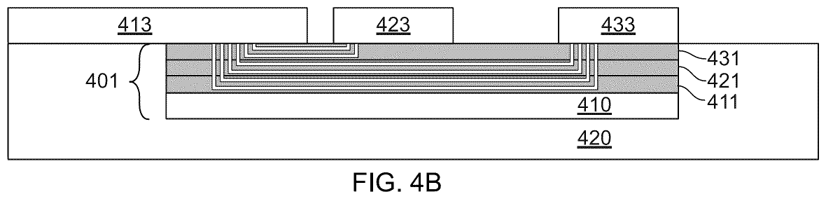

FIG. 4A shows examples of stacked substrates with embedded interconnects of varying L/S (width of line/space between lines). An interconnect covering a longer distance would have a higher resistivity than a similar interconnect covering a shorter distance. To make the resistivity of the interconnects similar, the longer interconnect can be made to be thicker and/or wider. Interconnects with a coarse L/S may be used for longer distances, whereas interconnects with a fine L/S may be used for shorter distances. A coarse L/S may be about 5-10 microns, or over about 5 microns. A fine L/S may be about 1-2 microns, or under about 5 microns. As an example, FIG. 4A shows interconnects (e.g., metal layer 424) covering a longer distance having thickness t1 that is greater than a thickness t2 of interconnects (e.g., metal layer 434) covering a shorter distance.

The stacked interconnect structure 401 comprises three substrates (e.g., first substrate 411, second substrate 421, and third substrate 431) that are attached (e.g., hybrid bonded) together. Each of the three substrates 411, 421, and 431, comprises dielectric layers 412, 422, and 432, respectively. The dielectric layers 412, 442, and 432 may be similar to dielectric layers 112 and 122 and comprise any suitable dielectric layer or layers, such as those mentioned throughout the present disclosure. A silicon layer 410 may be disposed below the dielectric layer 412. The dielectric layer 412 comprises embedded first interconnects (e.g., horizontal portion or metal layer 414 connected to a corresponding pair of vertical portions or metal connectors connected to each end of a horizontal portion or metal layer 414) with a coarse L/S. The dielectric layer 422 comprises embedded second interconnects (e.g., horizontal portion or metal layer 424 and corresponding pair of vertical portions or metal connectors connected to each end of a horizontal portion or metal layer 424) with a coarse L/S, similar to first interconnects. The dielectric layer 432 comprises embedded third interconnects (e.g., horizontal portion or metal layer 434 with corresponding pair of vertical portions or metal connectors 439 connected to each end of a horizontal portion or metal layer 434) with a fine L/S. The metal connectors 439 of the third interconnects are exposed. Metal vias 438 and 436 with a coarse L/S are embedded in the third substrate 431 in addition to the fine L/S third interconnects. Vias 438 correspond to and are connected to second interconnects (e.g., metal layers 424 and corresponding connectors), and vias 436 correspond to and are connected to first interconnects (e.g., metal layers 414 and corresponding connectors). The fine L/S third interconnects (e.g., metal layers 434 and corresponding connectors 439) may be shorter than the coarse L/S first and second interconnects (e.g., metal layers 414 and corresponding connectors, metal layers 424 and corresponding connectors).

Stacked interconnect structure 402 is similar to the stacked interconnect structure 401, except that more than one third substrates, such as substrates 441 and 451 are used in place of a single third substrate 431. Substrates 441 and 451 are similar to portions of the third substrate 431, and each has a smaller area than the third substrate 431. Using substrates with a smaller area may help reduce costs, and may be possible when shorter interconnects (e.g., interconnects with a fine L/S that are shorter) are present. Substrate 441 comprises dielectric layer 442, and substrate 451 comprises dielectric layer 452. Dielectric layer 442 and dielectric layer 452 may be similar to dielectric layer 112 and comprise any suitable dielectric layer or layers, such as those mentioned throughout the present disclosure. In some embodiments, fine and coarse L/S interconnects are disposed in the dielectric layer 442, whereas only coarse L/S interconnects are disposed in the dielectric layer 452. The metal layers, metal connectors, and vias of FIGS. 4A-4B may be similar to metal layers 114, 124, metal connectors 116, 126, and vias 126, respectively, and comprise any suitable metal or conductive materials such as those mentioned in the present disclosure.

FIG. 4B shows interconnect structure 401 used to connect chips 413, 423, and 433 together. Chips 413, 423, and 433 may be attached (e.g., bonded, hybrid bonded, etc.) to the interconnect structure 401. In some embodiments, chip 413 (e.g., CPU, GPU) may be connected to chips 423 (e.g., first HBM) and 433 (e.g., second HBM), but chip 423 (e.g., first HBM) may be at a shorter distance than a distance to chip 413 (e.g., CPU, GPU) than chip 433 (e.g., second HBM). Interconnects with a fine L/S (e.g., under 5 microns, about 1-2 microns) may be used to connect chip 413 to chip 423, and interconnects with a coarse L/S (e.g., over 5 microns, about 5-10 microns) may be to connect chip 413 to chip 433. The interconnect structure 401 may be disposed in a packaging substrate 420 (e.g., PCB, organic, ceramic, glass, etc.). In some embodiments, at least one dimension (e.g., length) of chip 423 may be within a length of substrate 431, and chip 413 may overlay substrate 431 and packaging substrate 420. In some embodiments, a length of one chip 423 may be within a length of an interconnect structure 401, and a length of another chip 413 may overlap a portion of a length of a packaging substrate 420 and a portion of a length of interconnect structure 401. In some embodiments, a footprint of one chip 423 may be within a footprint of an interconnect structure 401, and a footprint of another chip 413 may overlap a portion of a footprint of a packaging substrate 420 and a portion of a footprint of the interconnect structure 401. An edge portion of a footprint of chip 413 may overlap an edge portion of a footprint of the interconnect structure 401, and another portion of the chip 413 may overlap a portion of the packaging substrate 420.

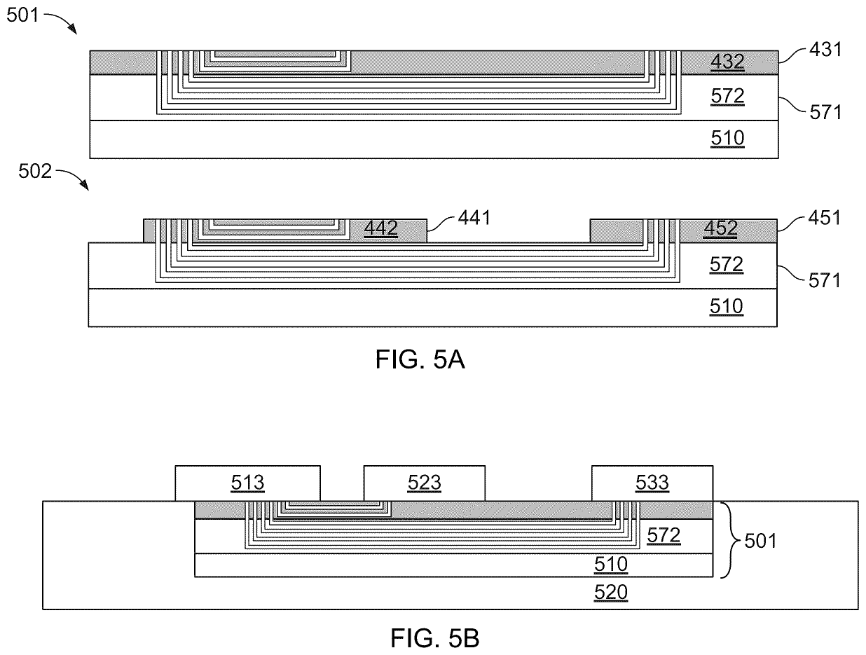

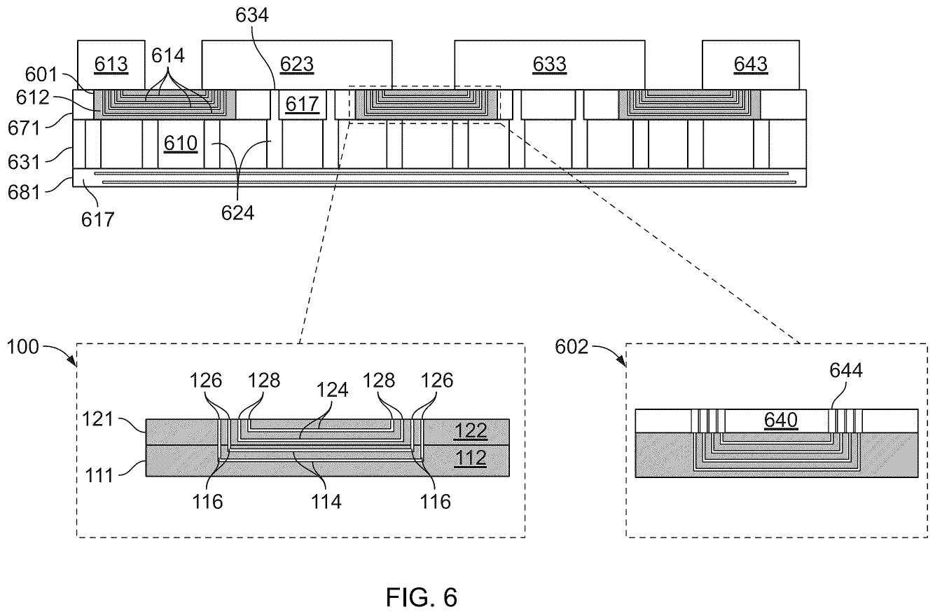

FIGS. 5A-5B show examples of stacked interconnect structures with interconnects of varying L/S (width of line/space between lines) similar to those shown in FIGS. 4A-4B, except the substrates 421 and 411 may be replaced with a substrate comprising organic material. For example, a substrate may be a redistribution layer comprising metal routing lines in an organic layer. The organic material may comprise materials such as PI, PBO, BCB, EMC resin, epoxy, resin, or molding material, etc. There may be a cost advantage of using organic RDLs as opposed to using inorganic dielectric materials, as forming metal layers in an organic material is generally a lower cost process. One or more inorganic dielectric layers (e.g., silicon oxide, silicon nitride, silicon oxynitride, silicon carbonitride, etc.) may be on top of the RDL layer(s) to attach the interconnect structure via hybrid bonding to another substrate. In some embodiments, the interconnects with a coarse L/S (e.g., over 5 microns, about 5-10 microns) are disposed in the organic RDL, while the interconnects with a fine L/S (e.g., under 5 microns, about 1-2 microns) are embedded in the inorganic dielectric layers.

Stacked interconnect structure 501 comprises two substrates: first substrate 571 and second substrate 431. The first substrate 571 comprises an organic layer 572. A silicon layer 510 is below the organic layer 572. Substrate 431 comprises dielectric layer 432. The first substrate 571 may comprise embedded interconnects with a coarse L/S (e.g., over 5 microns, about 5-10 microns). The dielectric layer 432 comprises embedded interconnects 434 with a fine L/S (e.g., under 5 microns, about 1-2 microns) and metal vias that correspond to and are connected to the coarse L/S interconnects in organic layer 572.

Stacked interconnect structure 502 is similar to stacked interconnect structure 501, except there may be more than one second substrates, such as substrates 441 and 451 in this example. Substrates 441 and 451 are similar to second substrate 431 in stacked interconnect structure 501, but each has smaller is area than the third substrate 431. Using a smaller area of substrate may help reduce costs, and may be possible when shorter interconnects (e.g., interconnects with a fine L/S that are shorter) are present. Substrate 441 comprises dielectric layer 442, and substrate 451 comprises dielectric layer 452. In some embodiments, fine and coarse L/S interconnects may be disposed in the dielectric layer 442, whereas only coarse L/S interconnects may be disposed in the dielectric layer 452.

In FIG. 5B, stacked interconnect structure 501 has been used to connect chips 513, 523, and 533 together more efficiently. In some embodiments, chip 513 (e.g., CPU, GPU) may be connected to chips 523 (e.g., first HBM) and 533 (e.g., second HBM), but chip 523 (e.g., first HBM) may be at a shorter distance than a distance to chip 513 (e.g., CPU, GPU) than chip 533 (e.g., second HBM). Interconnects with a fine L/S may be used to connect chip 513 to chip 523, and interconnects with a coarse L/S may be used to connect chip 513 to chip 533. The stacked interconnect structure 501 may be disposed in a packaging substrate 520 (e.g., PCB, organic, ceramic, glass, etc.).

FIG. 6 is an illustrative schematic sectional side view of an example interconnect structure which connects chips using bridges and an interposer, in accordance with embodiments of the present disclosure. The interconnect structures may be bridge structures. In some embodiments, the bridge structure comprises a single substrate. In some embodiments, the bridges may comprise multiple stacked substrates, each substrate comprising dielectric or silicon layers with embedded interconnects.

In FIG. 6, an interposer 631 is disposed on an interconnect layer 681 comprising a dielectric material 617 (e.g., organic material, inorganic material, or some combination thereof) and interconnects disposed in the dielectric material. The interposer 631 may comprise a silicon layer 610. Alternating bridges 601 (e.g., interconnect structures) and fill layers 671 comprising dielectric material 617 may be attached to or disposed on the interposer 631, similar to a silicon bridge structure. The bridges 601 may comprise one or more dielectric layers 612 (e.g., silicon oxide, silicon nitride, etc.) with embedded interconnects (e.g., metal layers 614, metal connectors, metal vias, etc.). In some embodiments, bridges 601 may be similar to interconnect structure 100 except four metal layers may be formed on one substrate instead of two metal layers on two separate substrates that are subsequently bonded. Alternatively, structures such as interconnect structure 100 in FIG. 1A, or interconnect structure 602, comprising a silicon layer 640 with conductive features 644 (e.g., DBI layer) disposed on bridge 601, may be used in place of bridge 601. The bridges 601, interconnect structures 100, or interconnect structures 602, can be used to connect chips 613, 623, 633, and 643 together. In some embodiments, all chips may not be connected to each other. A first chip 613 and a second chip 623 may be connected with a first interconnect structure 601 (e.g., left most interconnect structure 601 in FIG. 6). A second chip 623 and a third chip 633 may be connected with a second interconnect structure (e.g., center interconnect structure 601 in FIG. 6). A third chip 633 and a fourth chip 643 may be connected with a third interconnect structure (e.g., right most interconnect structure 601 in FIG. 6). In some embodiments, the chips may be any suitable chip (e.g., CPU, GPU, HBM, etc.). In some embodiments, chip 633 may be a CPU or a GPU chip, and chips 623 and 643 may be HBM chips. In some embodiments, chip 623 and chip 633 may be a CPU or GPU chips, and chips 613 and chip 643 may be HBM chips.

In some embodiments, the interposer 631 may comprise metal vias 624 and the fill layers 671 may comprise metal vias 634 to connect one or more of the chips 613, 623, 633, and 643 directly to the interconnect layer 681. In one of the embodiments, one or more of chips 613, 623, 633, and 643 can be a chip stack or stack of chips.

FIG. 7 shows illustrative schematic sectional side views of forming an interconnect structure which connects chips using bridges and an interposer at different stages of manufacturing to illustrate aspects of the method, in accordance with embodiments of the present disclosure.

At block 70, the method may comprise providing an interposer 631 and bridges 601. The interposer 631 may comprise a silicon layer 610 and metal vias 624 (e.g., TSVs). The method may comprise forming one or more bridges 601 with embedded interconnects. The bridges 601 may be disposed on substrates 720 (e.g., silicon layers). In some embodiments, alternative structures (e.g., interconnect structure 100, interconnect structure 602, etc.) may be used as bridges instead of bridges 601. In some embodiments, interposer 631 may have one or more RDLs on one or both of its surfaces (e.g., top surface and/or bottom surface).

At block 71, bridges 601 may be attached (e.g., hybrid bonded, direct bonded, soldered, adhesive bonded or attached using any other suitable means, etc.) to the interposer 631. There may be gaps formed between the bridges 601.

At block 71, the substrates 720 (e.g., silicon layers) may be removed from the bridges 601. For example, the substrates 720 or silicon layers may be etched.

At block 73, the gaps between the bridges 601 may be filled (e.g., by deposition) with dielectric material 617. Metal vias 634 may be formed in the dielectric material 617, and may correspond to and be connected to the metal vias 624 in the interposer 631. In some embodiments, metal vias 634 may be electrically connected to RDL formed on top of the interposer 631. In some embodiments, metal posts may be formed first and dielectric material 617 may fill the gaps between the bridges. The dielectric material 617 may be any suitable dielectric material such as those mentioned throughout the present disclosure. The dielectric material 617 may be an organic material (e.g., PI, PBO, BCB, EMC resin, epoxy, resin, or molding material, etc.), an inorganic material (e.g., silicon oxide, nitride, oxynitride, carbonitride, etc.), or some combination thereof. The structure in block 73 may be used to connect chips (e.g., CPUs, GPUs, HBMs), such as in FIG. 6.

In some embodiments, the dielectric material used to make dielectric layers may comprise a combination of inorganic materials, organic materials, or both inorganic and organic materials. For example, the dielectric material may comprise a combination of inorganic materials such as silicon oxide, silicon nitride, or silicon oxynitride, silicon carbide, silicon oxycarbonitride, low K dielectric materials, SiCOH dielectrics, silicon carbonitride or diamond-like carbon or a material comprising a diamond surface. The dielectric material may comprise a combination of organic materials such as PI, PBO, BCB, EMC resin, epoxy, resin, or molding material. The dielectric material may comprise a combination of inorganic and organic materials, such as those mentioned throughout the present disclosure.

In some embodiments, the metal used to make the metal interconnects (e.g., metal layers, metal connectors, metal vias, etc.) may comprise copper, copper alloys, nickel, nickel alloys, aluminum, aluminum alloys, etc.

In some embodiments, interfaces to a metal interconnects (e.g., metal layers, metal connectors, metal vias, etc.) may comprise a nitride layer. A nitride layer may serve as a barrier layer for metal (e.g., copper).

In some embodiments, use of a DBI bonding layer may provide for larger conductive features for bonding. Exposed bond pads or conductive features in a DBI bonding layer on an interconnect structure may be larger in size than connectors of interconnects in an interconnect structure.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a bond interface 818 without an intervening adhesive. Conductive features 806a of a first element 802 may be electrically connected to corresponding conductive features 80b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitride, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Årms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

The embodiments discussed above are intended to be illustrative and not limiting. One skilled in the art would appreciate that individual aspects of the interconnect structures, stacked interconnect structures, and methods discussed herein may be omitted, modified, combined, and/or rearranged without departing from the scope of the disclosure.

1. An interconnect structure comprising:
a first substrate comprising one or more first interconnects embedded in a first dielectric layer; and
a second substrate attached to the first substrate, the second substrate comprising one or more second interconnects embedded in a second dielectric layer and one or more pairs of vias through the second dielectric layer, wherein:
each interconnect comprises a metal layer extending along a first direction and a pair of metal connectors extending from the metal layer in a second direction to a surface of the respective substrate; and
at least one pair of vias through the second dielectric layer is connected to at least one pair of connectors of the first substrate, wherein the interconnect structure comprises at least one interconnect comprising a pair of vias of the second substrate connected a first interconnect of the first substrate and at least another interconnect comprising a second interconnect of the second substrate.

2. The interconnect structure of claim 1, further comprising conductive features disposed in a silicon layer on the second substrate, wherein each conductive feature is connected to a respective interconnect.

3. The interconnect structure of claim 1, wherein the first substrate is disposed on a silicon layer, and one or more through silicon vias through the silicon layer is connected to a corresponding first interconnect through a connector disposed in the first dielectric layer.

4. The interconnect structure of claim 1, further comprising through silicon vias disposed in a silicon layer between the first substrate and the second substrate, wherein the through silicon vias connect the at least one pair of vias through the second dielectric layer to the at least one pair of connectors of the first substrate.

5. The interconnect structure of claim 1, wherein:
the one or more pairs of vias are first vias; and
the interconnect structure further comprises a third substrate attached to the second substrate, the third substrate comprising:
one or more third interconnects embedded in a third dielectric layer;
one or more pairs of second vias, wherein at least one pair of second vias is electrically connected to the at least one pair of first vias; and
one or more pairs of third vias disposed in the third substrate, wherein at least one pair of third vias is connected to at least one pair of connectors of the one or more second interconnects.

6. The interconnect structure of claim 5, wherein the one or more second interconnects have a line/space of about 5 microns/5 microns to about 10 microns/10 microns and the one or more third interconnects have a line/space of about 1 micron/1 micron to about 2 microns/2 microns.

7. The interconnect structure of claim 1, wherein:
the one or more pairs of vias are first vias;
the interconnect structure further comprises a third substrate attached to the second substrate and a fourth substrate attached to the second substrate;
the third substrate comprises one or more third interconnects embedded in a third dielectric layer; and
each of the third substrate and the fourth substrate comprises:
one or more second vias disposed in a respective substrate, wherein at least one second via is electrically connected to the at least one first via; and
one or more third vias disposed in a respective substrate, wherein at least one third via is connected to at least one connector of the one or more second interconnects.

8. The interconnect structure of claim 1, wherein the first dielectric layer comprises organic material, and the second dielectric layer comprises inorganic material.

9. A method of manufacturing an interconnect structure, the method comprising:
providing a first substrate and a second substrate, the first substrate comprising one or more first interconnects embedded in a first dielectric layer, and the second substrate comprising one or more second interconnects embedded in a second dielectric layer and one or more pairs of vias, wherein each interconnect comprises a metal layer extending along a first direction and a pair of metal connectors extending from the metal layer in a second direction to a surface of the respective substrate; and
bonding the first substrate to the second substrate to connect at least one pair of vias of the second substrate to at least one pair of connectors of the first substrate, wherein the interconnect structure comprises at least one interconnect comprising a pair of vias of the second substrate connected a first interconnect of the first substrate and at least another interconnect comprising a second interconnect of the second substrate.

10. The method of claim 9, wherein:
the first substrate further comprises a first silicon layer;
the second substrate further comprises a second silicon layer; and
the method further comprises removing the second silicon layer.

11. The method of claim 9, wherein:
the first substrate further comprises a first silicon layer;
the second substrate further comprises a second silicon layer and one or more pairs of partial through silicon vias embedded in the second silicon layer, each partial through silicon via comprising a first end connecting to a corresponding interconnect or via through the second dielectric layer and comprising a second end embedded in the second silicon layer; and
the method further comprises partially removing the second silicon layer to form a bond pad.

12. The method of claim 9, wherein:
the first substrate is disposed on a silicon layer; and
the method further comprises: forming one or more through silicon vias through the silicon layer to connect to a corresponding first interconnect through a connector disposed in the first dielectric layer.

13. The method of claim 9, wherein:
the one or more pairs of vias are first vias; and
the method further comprises:
providing a third substrate comprising one or more third interconnects embedded in a third dielectric layer, one or more pair of second vias through the third dielectric layer, and one or more pairs of third vias through the third dielectric layer; and
bonding the third substrate to the second substrate to electrically connect at least one pair of second vias to the at least one pair of first vias and to connect at least one pair of third vias to at least one pair of connectors of the one or more second interconnects.

14. A method comprising:
providing at least one interconnect structure, wherein:
each interconnect structure comprises bonded first and second substrates;
each first substrate comprises one or more first interconnects embedded in a first dielectric layer;
each second substrate comprises one or more second interconnects embedded in a second dielectric layer and one or more pairs of vias; and
each interconnect structure comprises at least one interconnect comprising a pair of vias of the second substrate connected a first interconnect of the first substrate and at least another interconnect comprising a second interconnect of the second substrate;
providing an interposer comprising a silicon layer and one or more through silicon vias; and
bonding the at least one interconnect structure to the interposer.

15. The method of claim 14, wherein bonding the at least one interconnect structure to the interposer comprises directly bonding the at least one interconnect structure to the interposer.

16. The method of claim 14, wherein bonding the at least one interconnect structure to the interposer comprises directly hybrid bonding the at least one interconnect structure to the interposer.

17. The method of claim 14, wherein:
a carrier substrate is attached to the at least one interconnect structure prior to bonding the at least one interconnect structure to the interposer; and
the method further comprises removing the carrier substrate from the at least one interconnect structure.

18. The method of claim 14, further comprising:
forming an organic material layer to dispose the at least one interconnect structure in the organic material layer; and
forming one or more conductive vias in the organic material layer to connect to the one or more through silicon vias of the interposer.

19. The method of claim 14, further comprising:
forming one or more conductive posts adjacent to the at least one interconnect structure to connect to the one or more through silicon vias of the interposer; and
forming an organic material layer to dispose the at least one interconnect structure and the one or more conductive posts in the organic material layer.

20. The method of claim 14, further comprising:
hybrid bonding a first semiconductor device and a second semiconductor device to the second substrate of the at least one interconnect structure, wherein the first semiconductor device is electrically connected to the second semiconductor device through the at least one interconnect and the at least another interconnect of the interconnect structure.
